(19) United States
(12) Patent Application Publication
(10) Pub. No.: US 2023/0063899 A1
(43) Pub. Date: Mar. 2, 2023

(54) Cutting Machining Apparatus

(71) Applicant: NISSIN MANUFACTURING CO., LTD., Kyoto (JP)

(72) Inventors: Shuhei Muraoka, Kyoto (JP); Tomoya Yabunaka, Kyoto (JP); Kazuhiro Tanaka, Kyoto (JP)

(21) Appl. No.: 17/797,934

(22) PCT Filed: Feb. 5, 2021
(86) PCT No.: PCT/JP2021/004362

§ 371 Date: Aug. 5, 2022

(30) Foreign Application Priority Data
Feb. 6, 2020 (JP) 2020-018548

(51) Int. Cl. B23Q 1/01; B23Q 1/56

(52) U.S. Cl. CPC B23Q 1/01; B23Q 1/56

(57) ABSTRACT

A cutting machining apparatus includes a rectangular box-shaped housing as a whole, a base member fixed to the housing via a cushioning member, a workpiece holder disposed inside the housing to be apart from the housing, fixed to the base member, and holding a workpiece, and a machining unit disposed inside the housing to be apart from the housing, fixed to the base member, and machining the workpiece.

### FIELD OF THE INVENTION

The present disclosure relates to a cutting machining apparatus.

### BACKGROUND OF THE INVENTION

There has been proposed a processing device including a flat base member having a rectangular shape in a plan view, a pair of side members extending vertically upward from both ends of the base member corresponding to two sides facing each other in the plan view, a guide rail having a long rectangular plate shape and supported by the pair of side members at both ends of the guide rail in a longitudinal direction, a shaft, a carriage slidably supported on each of the guide rail and the shaft, and a workpiece holding device fixed to the base member and holding a workpiece (for example, see Patent Literature 1). In the processing device, a main shaft on which a processing tool is mounted is arranged to be movable in the vertical direction in the carriage.

### SUMMARY OF THE INVENTION

### Technical Problem

However, in the processing device disclosed in Patent Literature 1, when the side members are relatively distorted or vibrated with respect to the base member, it affects the positional relationship between the workpiece held by the workpiece holding device and the main shaft on which the machining tool is mounted. Therefore, the machining accuracy of the workpiece may be reduced.

The present disclosure has been made to solve the above problems, and an objective of the present disclosure is to provide a cutting machining apparatus with improved machining accuracy.

### Solution to Problem

In order to achieve the above objective, a cutting machining apparatus according to the present disclosure includes:
a housing;
a base member connected to the housing via a cushioning member;
a to-be-machined object holder fixed to the base member inside the housing in a state of being separated from the housing and holding a to-be-machined object; and
a machining unit vertically installed on the base member inside the housing in a state of being separated from the housing and machining the to-be-machined object.

### Advantageous Effects of Invention

According to the present disclosure, the base member is connected to the housing via the cushioning member. The to-be-machined object holder is fixed to the base member inside the housing in a state of being separated from the housing, and the machining unit is vertically installed on the base member inside the housing in a state of being separated from the housing. In this way, since the to-be-machined object holder and the machining unit are fixed to the common base member in the state of being separated from the housing, even though the housing is relatively distorted or vibrated with respect to the base member, the positional relationship between the to-be-machined object held by the to-be-machined object holder and the machining unit is maintained. Consequently, the machining accuracy of the to-be-machined object can be improved.

### BRIEF DESCRIPTION OF THE DRAWINGS

FIG. 1 is a cross-sectional view of a cutting machining apparatus according to an embodiment of the present disclosure;

FIG. 2 is a cross-sectional view of the cutting machining apparatus according to the embodiment;

FIG. 3 is a perspective view of the cutting machining apparatus according to the embodiment;

FIG. 4 is a perspective view illustrating a part of the cutting machining apparatus according to the embodiment;

FIG. 5 is a rear view of the cutting machining apparatus according to the embodiment; and

FIG. 6 is a cross-sectional view of a cutting machining apparatus according to a modification.

### DETAILED DESCRIPTION OF THE INVENTION

Hereinafter, a cutting machining apparatus according to embodiments of the present disclosure is described with reference to the drawings. The cutting machining apparatus according to the present embodiment includes a housing, a base member connected to the housing via a cushioning member, a to-be-machined object holder fixed to the base member inside the housing in a state of being separated from the housing and holding a to-be-machined object, and a machining unit vertically installed on the base member inside the housing in a state of being separated from the housing and machining the to-be-machined object. Furthermore, the cutting machining apparatus according to the present embodiment is a so-called desktop type small cutting machining apparatus used when a dental technician creates a denture or a prosthesis, for example, and improves machining accuracy by reducing the influence of distortion or vibration of the housing.

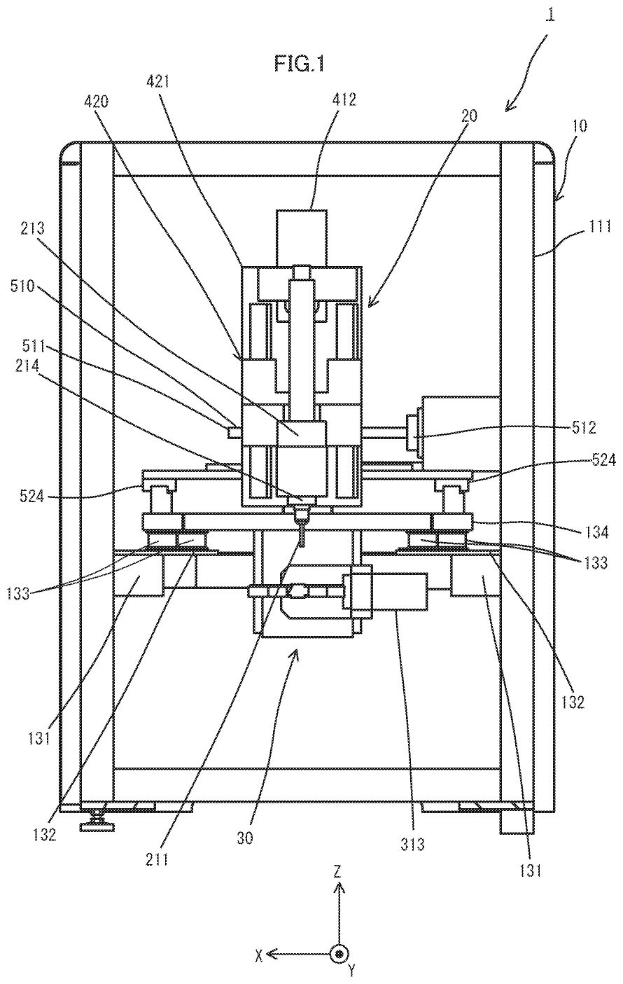

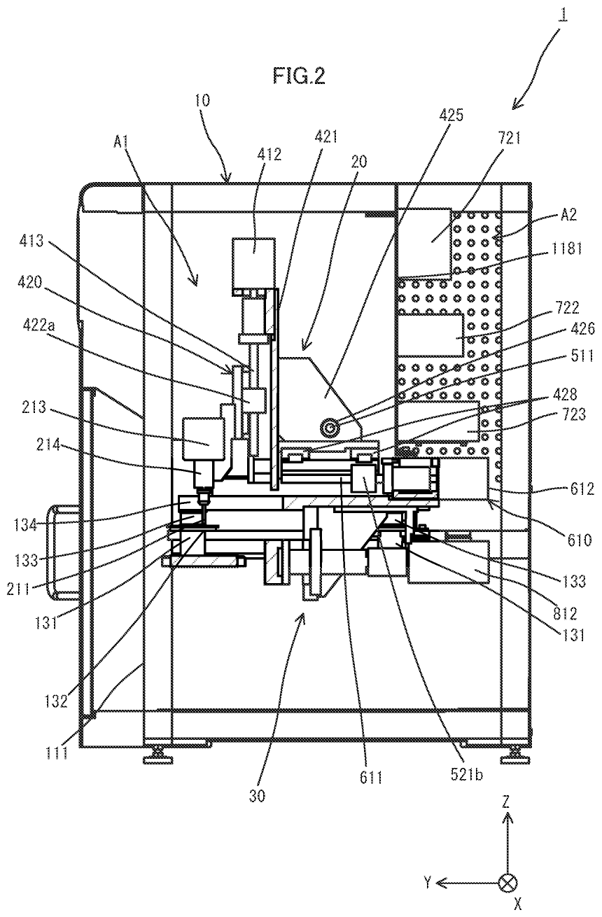

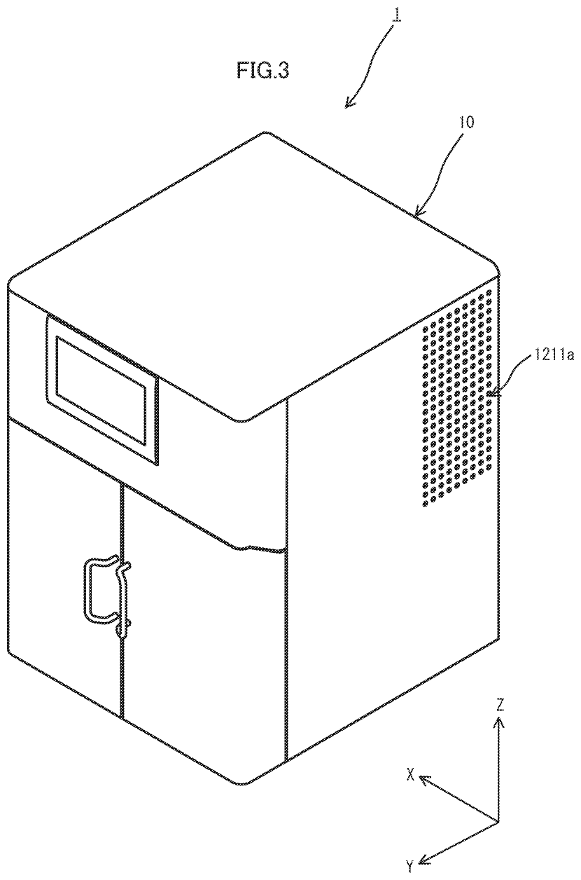

As illustrated in FIG. 1, the cutting machining apparatus 1 according to the present embodiment is a so-called desktop type small cutting machining apparatus, and incudes a machining unit 20, a base member 134, a workpiece holder 30, a housing 10, and cushioning members 133. Hereinafter, a +Z direction is described as vertically upward and a −Z direction is described as vertically downward as appropriate. As illustrated in FIG. 2, the cutting machining apparatus 1 further includes control boards 721, 722, and 723 that control the machining unit 20 and the workpiece holder 30. The machining unit 20 is for cutting a workpiece, and includes a tool 211, a main shaft 214 having a long cylindrical shape, a rotation driver 213, and a rotation driver supporter 420. The machining unit 20 further includes an X-axis direction driver 510 and a Y-axis direction driver 610 to be described below. The tool 211 is, for example, an end mill, a milling bar, a brush, or the like. The tool 211 is attached to a lower end of the main shaft 214. The rotation driver 213 is a motor and rotationally drives the main shaft 214. The housing 10 has a rectangular box shape as illustrated in FIG. 3.

As illustrated in FIG. 2, the rotation driver supporter 420 includes a main part 421 having a plate shape, a saddle 425, and a nut 426. The main part 421 has a rectangular plate shape, supports the rotation driver 213 on a +Y direction side, and is disposed parallel to the Z-axis direction. The saddle 425 has a plate shape and protrudes from a −Y direction side of the main part 421 in a second direction, that is, along a Y-axis direction. The nut 426 is disposed so that its central axis is along a first direction, that is, an X-axis direction, and is embedded in the saddle 425 to penetrate the saddle 425 along the X-axis direction. As a result, a ball screw 511 and a ball screw driver 512 of the X-axis direction driver 510 to be described below can be disposed on the side of the main part 421, so that the entire rotation driver supporter 420 can be brought closer to the workpiece holder 30 to that extent.

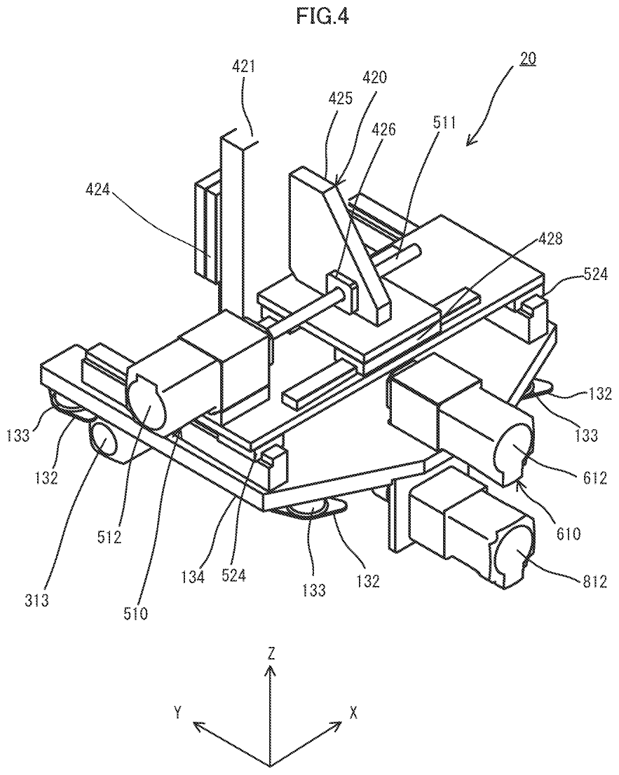

As illustrated in FIG. 4, the machining unit 20 includes a rail (not illustrated) extending in the Z-axis direction on the +Y direction side of the main part 421, and a slide block 424 slidably mounted on the rail. The slide block 424 is fixed to the rotation driver 213, and the rotation driver 213 is slidable along the rail. As illustrated in FIG. 2, the machining unit 20 further includes a ball screw 413, a ball screw driver 412 that rotationally drives the ball screw 413, and a support member (not illustrated) that supports the ball screw driver 412 inward and is fixed to the main part 421. The ball screw driver 412 is a motor, and moves the rotation driver 213 fixed to the slide block 424 along the rail by rotating the ball screw 413 around a central axis along the longitudinal direction thereof.

As illustrated in FIG. 4, the X-axis direction driver 510 is a horizontal driver that moves the rotation driver supporter 420 in the first direction orthogonal to the vertical direction, that is, in the X-axis direction. The X-axis direction driver 510 includes slide blocks 428 movable along the X-axis direction. The slide block 428 is fixed to the rotation driver supporter 420, and the rotation driver supporter 420 is movable along the X-axis direction. The X-axis direction driver 510 further includes the ball screw 511 disposed along the X-axis direction and the ball screw driver 512 that rotationally drives the ball screw 511. The ball screw driver 512 is a motor, and moves the entire rotation driver supporter 420 in the X-axis direction by rotating the ball screw 511 around a central axis along the longitudinal direction thereof. The ball screw 511 is screwed into the nut 426 of the rotation driver supporter 420.

The Y-axis direction driver 610 is a horizontal driver that moves the rotation driver supporter 420 in the second direction orthogonal to the vertical direction, that is, in the Y-axis direction. The Y-axis direction driver 610 includes slide blocks 524 movable along the Y-axis direction on the +Z direction side of the base member 134. The slide blocks 524 are indirectly fixed to the rotation driver supporter 420, and the rotation driver supporter 420 is movable along the Y-axis direction. As illustrated in FIG. 2, the Y-axis direction driver 610 further includes a ball screw 611 disposed along the Y-axis direction and a ball screw driver 612 that rotationally drives the ball screw 611. The ball screw driver 612 is a motor, and moves the rotation driver supporter 420 in the Y-axis direction by rotating the ball screw 611 around a central axis along the longitudinal direction thereof. The ball screw 611 is screwed into a nut 521b protruding in the −Z direction side of the rotation driver supporter 420.

The workpiece holder 30 holds a workpiece to be machined, and as illustrated in FIG. 1, is a to-be-machined object holder including a rotation driver 313 that tilts the workpiece in the direction of rotation about an X axis. As illustrated in FIG. 2, the workpiece holder 30 further includes a rotation driver 812 that tilts the workpiece in the direction of rotation about a Y axis. The rotation driver 812 is fixed to the base member 134.

The control boards 721, 722, and 723 include heat generating components such as resistors and transistors mounted thereon, and control currents supplied to the rotation driver 213 and the ball screw drivers 412, 512, and 612 of the machining unit 20 and control operations of the rotation driver 213 and the ball screw drivers 412, 512, and 612. The control boards 721, 722, and 723 control currents supplied to the rotation drivers 313 and 812 of the workpiece holder 30 and control operations of the rotation drivers 313 and 812.

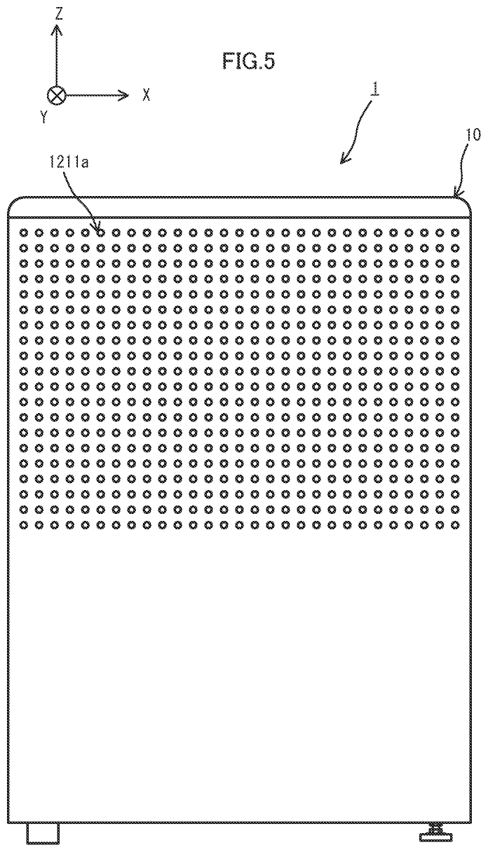

The housing 10 includes a pair of frame sets 111 disposed to be apart from each other in the X-axis direction with the workpiece holder 30 and the machining unit 20 interposed therebetween. Each of the frame sets 111 includes, for example, two pillar frames arranged in parallel in the Y-axis direction and extending in the Z-axis direction, and at least one beam frame extending in the Y-axis direction to connect the two pillar frames to each other. The housing 10 further includes a partition wall 1181. The control boards 721, 722, and 723 are fixed on the −Y direction side of the partition wall 1181. The partition wall 1181 is fixed to the frame sets 111. The partition wall 1181 is disposed between a first region A1 where the base member 134, the workpiece holder 30, and the machining unit 20 are disposed, and a second region A2 where the control boards 721, 722, and 723 are disposed, and separates the first region A1 and the second region A2. As illustrated in FIG. 3 and FIG. 5, a plurality of communication holes 1211a communicating from the second region A2 to the outside of the housing 10 is formed in a portion of a peripheral wall of the housing 10, which corresponds to the second region A2. The plurality of communication holes 1211a is formed in at least the entire peripheral wall of the housing 10 on the +Z direction side above the center in the Z-axis direction of the portion corresponding to the second region A2. As a result, air warmed by heat generated in the control boards 721, 722, and 723 in the second region A2 and moved vertically upward in the second region A2 can be efficiently discharged to the outside of the housing 10.

As illustrated in FIG. 1, the housing 10 further includes a support plate 132 for supporting the base member 134, and plate fixing members 131 for fixing the support plate 132 to the frame sets 111 of the housing 10. The plate fixing member 131 has a rectangular parallelepiped outer shape, and is fixed to each of the pair of frame sets 111 in a state of protruding in a direction approaching each other. As illustrated in FIG. 2, the plate fixing members 131 are fixed to the frame sets 111. The support plate 132 has a plate shape and is fixed to the +Z direction side of each of the plate fixing members 131.

The cushioning member 133 is formed in a tubular shape using an elastic material such as rubber or elastomer, and is fixed to the +Z direction side of the support plate 132 in an orientation in which the tubular axis direction is parallel to the Z-axis direction. The cushioning member 133 is formed of a material having heat insulating properties.

As described above, in the cutting machining apparatus 1 according to the present embodiment, the base member 134 is connected to the housing 10 via the cushioning members 133. The workpiece holder 30 is fixed to the base member 134 inside the housing 10 in a state of being separated from the housing 10, and the machining unit 20 is vertically installed on the base member 134 inside the housing 10 in a state of being separated from the housing 10. In this way, since the workpiece holder 30 and the machining unit 20 are fixed to the common base member 134 in the state of being separated from the housing 10, even though the housing 10 is relatively distorted or vibrated with respect to the base member 134, the positional relationship between a workpiece held by the workpiece holder 30 and the machining unit 20 is maintained. Consequently, the machining accuracy of the workpiece can be improved.

For example, when the housing 10 is vibrating, the vibration of the housing 10 is transmitted to the workpiece holder 30 and the machining unit 20 via the base member 134 supported by the cushioning members 133. Therefore, the vibrations transmitted to the workpiece holder 30 and the machining unit 20 are always synchronized. Therefore, the positional relationship between a workpiece held by the workpiece holder 30 and the machining unit 20 is maintained.

Furthermore, the housing 10 according to the present embodiment includes the pair of frame sets 111 disposed to be apart from each other with the workpiece holder 30 and the machining unit 20 interposed therebetween, and supports the base member 134 via the cushioning members 133. The plate fixing member 131 is fixed to each of the pair of frame sets 111 in a state of protruding in a direction approaching each other. This makes it possible to secure a space on the −Z direction side from the plate fixing member 131 in the housing 10. Furthermore, the workpiece holder 30 is fixed to the −Z direction side of the base member 134, and the machining unit 20 is fixed to the +Z direction side of the base member 134. Consequently, since a relatively wide space can be secured around the workpiece holder 30 located on the −Z direction side from the plate fixing member 131, there is an advantage that a workpiece can be easily attached to and detached from the workpiece holder 30.

Moreover, the rotation driver supporter 420 according to the present embodiment includes the main part 421 that supports the rotation driver 213 on the +Y direction side, the saddle 425 that protrudes from the −Y direction side of the main part 421 along the Y-axis direction, and the nut 426 embedded in the saddle 425. Furthermore, the X-axis direction driver 510 includes the slide blocks 428 disposed on the +X direction side of the base member 134 and movable along the X-axis direction, the ball screw 511 screwed into the nut 426, and the ball screw driver 512 that rotationally drives the ball screw 511. As a result, the ball screw 511 can be disposed above the rotation driver supporter 420, so that the rotation driver supporter 420 can be brought closer to the workpiece holder 30 side to that extent. As the distance between the rotation driver supporter 420 and the workpiece holder 30 becomes closer, the amount of displacement of a workpiece with respect to the main shaft 214 connected to the rotation driver 213 when external stress is applied to the rotation driver supporter 420 and the workpiece holder 30 can be reduced. Consequently, the machining accuracy of the workpiece can be improved.

Furthermore, heat generating components are mounted on the control boards 721, 722, and 723 according to the present embodiment, and the cushioning member 133 is formed of a material having heat insulating properties. The control boards 721, 722, and 723 are fixed to the partition wall 1181 of the housing 10. As a result, heat generated in the control boards 721, 722, and 723 and transmitted to the support plate 132 via the partition wall 1181, the frame sets 111, and the plate fixing member 131 is suppressed from being transmitted to the base member 134. Consequently, since the heat generated in the control boards 721, 722, and 723 is suppressed from being transmitted to the machining unit 20 and the workpiece holder 30, thermal deformation due to an increase in the temperature of the machining unit 20 and the workpiece holder 30 is suppressed. Consequently, the machining accuracy of a workpiece can be improved.

Moreover, in the housing 10 according to the present embodiment, the partition wall 1181 is disposed between the first region A1 where the base member 134, the workpiece holder 30, and the machining unit 20 are disposed, and the second region A2 where the control boards 721, 722, and 723 are disposed, and separates the first region A1 and the second region A2. As a result, air warmed by heat generated in the control boards 721, 722, and 723 and existing in the second region A2 can be suppressed from flowing into the first region A1. Consequently, thermal deformation due to an increase in the temperature of the base member 134, the workpiece holder 30, and the machining unit 20 disposed in the first region A1 is suppressed.

Furthermore, in the housing 10 according to the present embodiment, the plurality of communication holes 1211a communicating from the second region A2 to the outside of the housing 10 is formed in a portion of the housing 10, which corresponds to the second region A2. As a result, air warmed by heat generated in the control boards 721, 722, and 723 in the second region A2 can be discharged to the outside of the housing 10, so that an increase in the temperature of air existing in the housing 10 can be suppressed.

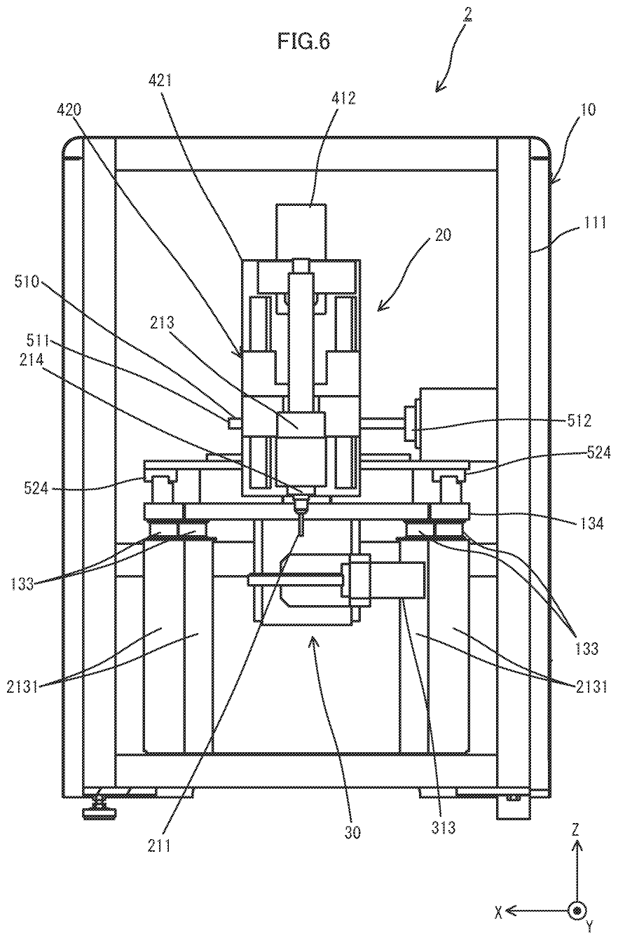

Although the embodiment of the present disclosure has been described above, the present disclosure is not limited to the configuration of the aforementioned embodiment. For example, as in a cutting machining apparatus 2 illustrated in FIG. 6, support members 2131 each having a long columnar shape and extending along the Z-axis direction to support the base member 134 may be provided. In FIG. 6, the same configurations as those in the embodiment are denoted by the same reference numerals as those in FIG. 1. The base member 134 is supported via the cushioning members 133 at ends of the support members 2131 on the +Z direction side. An end of the support member 2131 on the −Z direction side is long and extends along the Y-axis direction, and both ends in the longitudinal direction thereof are fixed to the lower end portion of the housing 10.

In the embodiment, an example in which the cushioning member 133 is a member formed of an elastic material such as rubber or elastomer has been described. However, the cushioning member 133 is not limited thereto, and may be configured using, for example, an air suspension or a magnetic spring.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

This application claims the benefit of Japanese Patent Application No. 2020-018548, filed on Feb. 6, 2020, the entire disclosure of which is incorporated by reference herein.

### INDUSTRIAL APPLICABILITY

The present disclosure is suitable as a dental prosthesis manufacturing apparatus for manufacturing a dental prosthesis by cutting a workpiece.

### REFERENCE SIGNS LIST

1, 2 Cutting machining apparatus
10 Housing
20 Machining unit
30 Workpiece holder
111 Frame set
131 Plate fixing member
132 Support plate
133 Cushioning member
134 Base member
2131 Support member
211 Tool
213, 313, 812 Rotation driver
214 Main shaft
412, 512, 612 Ball screw driver
413, 511, 611 Ball screw
420 Rotation driver supporter
421 Main part
426, 521b Nut
424, 428, 524 Slide block
425 Saddle
510 X-axis direction driver
610 Y-axis direction driver
721, 722, 723 Control board
1181 Partition wall
1211a Communication hole
2131 Support member
A1 First region
A2 Second region

1. A cutting machining apparatus, comprising:
a housing;
a base member connected to the housing via a cushioning member;
a to-be-machined object holder fixed to the base member inside the housing in a state of being separated from the housing and holding a to-be-machined object; and
a machining unit vertically installed on the base member inside the housing in a state of being separated from the housing and machining the to-be-machined object.

2. The cutting machining apparatus according to claim 1, wherein
the housing comprises:
a pair of frame sets disposed to be apart from each other with the to-be-machined object holder and the machining unit interposed therebetween;
a support plate supporting the base member via the cushioning member; and
a plate fixing member fixed to each of the pair of frame sets in a state of protruding in a direction approaching each other, the support plate being fixed to the plate fixing member.

3. The cutting machining apparatus according to claim 1, wherein
the to-be-machined object holder is fixed to a vertically lower side of the base member, and
the machining unit is fixed to a vertically upper side of the base member.

4. The cutting machining apparatus according to claim 3, wherein
the machining unit includes:
a main shaft on which a tool is mounted;
a rotation driver rotationally driving the main shaft;
a rotation driver supporter supporting the rotation driver; and
a horizontal driver moving the rotation driver supporter in a first direction orthogonal to a vertical direction,
the rotation driver supporter includes:
a main part having a plate shape, supporting the rotation driver on one surface side in a thickness direction, and disposed parallel to the vertical direction and the first direction;
a saddle protruding from the other surface side in the thickness direction of the main part along a second direction orthogonal to the first direction; and
a nut disposed to penetrate the saddle along the first direction, and
the horizontal driver includes:
a rail disposed vertically above the base member and laid along the first direction;
a slide block slidably supported on the rail along the rail and including the rotation driver supporter fixed on a vertically upper side;
a ball screw disposed along the first direction and screwed into the nut; and
a ball screw driver rotationally driving the ball screw.

5. The cutting machining apparatus according to claim 1, further comprising:
a control board mounted with a heat generating component and controlling the machining unit, wherein
the cushioning member is formed of a material having heat insulating properties, and
the control board is fixed to the housing.

6. The cutting machining apparatus according to claim 5, wherein the housing has a box shape and includes a partition wall disposed between a first region where the base member, the to-be-machined object holder, and the machining unit are disposed and a second region where the control board is disposed, and separating the first region and the second region.

7. The cutting machining apparatus according to claim 6, wherein the housing has at least one communication hole communicating from the second region to an outside of the housing in a portion of a peripheral wall of the housing, the portion corresponding to the second region.

8. The cutting machining apparatus according to claim 2, wherein
the to-be-machined object holder is fixed to a vertically lower side of the base member, and
the machining unit is fixed to a vertically upper side of the base member.

9. The cutting machining apparatus according to claim 8, wherein
the machining unit includes:
a main shaft on which a tool is mounted;
a rotation driver rotationally driving the main shaft;
a rotation driver supporter supporting the rotation driver; and
a horizontal driver moving the rotation driver supporter in a first direction orthogonal to a vertical direction,
the rotation driver supporter includes:
a main part having a plate shape, supporting the rotation driver on one surface side in a thickness direction, and disposed parallel to the vertical direction and the first direction;
a saddle protruding from the other surface side in the thickness direction of the main part along a second direction orthogonal to the first direction; and
a nut disposed to penetrate the saddle along the first direction, and
the horizontal driver includes:
a rail disposed vertically above the base member and laid along the first direction;
a slide block slidably supported on the rail along the rail and including the rotation driver supporter fixed on a vertically upper side;
a ball screw disposed along the first direction and screwed into the nut; and
a ball screw driver rotationally driving the ball screw.

10. The cutting machining apparatus according to claim 2, further comprising:
a control board mounted with a heat generating component and controlling the machining unit, wherein
the cushioning member is formed of a material having heat insulating properties, and
the control board is fixed to the housing.

11. The cutting machining apparatus according to claim 3, further comprising:
a control board mounted with a heat generating component and controlling the machining unit, wherein
the cushioning member is formed of a material having heat insulating properties, and
the control board is fixed to the housing.

12. The cutting machining apparatus according to claim 4, further comprising:
a control board mounted with a heat generating component and controlling the machining unit, wherein
the cushioning member is formed of a material having heat insulating properties, and
the control board is fixed to the housing.

13. The cutting machining apparatus according to claim 8, further comprising:
a control board mounted with a heat generating component and controlling the machining unit, wherein
the cushioning member is formed of a material having heat insulating properties, and
the control board is fixed to the housing.

14. The cutting machining apparatus according to claim 9, further comprising:
a control board mounted with a heat generating component and controlling the machining unit, wherein
the cushioning member is formed of a material having heat insulating properties, and
the control board is fixed to the housing.
